(19) United States
(12) Patent Application Publication
(10) Pub. No.: US 2024/0332783 A1
(43) Pub. Date: Oct. 3, 2024

(54) DISPLAY DEVICE

(71) Applicant: LG ELECTRONICS INC., Seoul (KR)

(72) Inventors: Joonsub BAE, Seoul (KR); Sangmoon HWANG, Seoul (KR); Jaejun LEE, Seoul (KR); Hansoo KIM, Seoul (KR); MinWoong SEO, Seoul (KR)

(73) Assignee: LG ELECTRONICS INC., Seoul (KR)

(21) Appl. No.: 18/577,498

(22) PCT Filed: Jul. 9, 2021
(86) PCT No.: PCT/KR2021/008841

§ 371 Date: Jan. 8, 2024

(51) Int. Cl. H01Q 1/24; H05K 9/00

(52) U.S. Cl. CPC H01Q 1/243; H05K 9/0054

(57) ABSTRACT

Disclosed is a display device. The display device of the present disclosure includes: a display panel; a frame which is located in a rear of the display panel, and to which the display panel is coupled; and a communication module which is adjacent to one side of the frame, is coupled to the frame, and has an antenna unit, wherein the communication module comprises a plate in contact with a rear surface of the antenna unit, wherein a portion of the plate is positioned spaced apart from the antenna unit.

### TECHNICAL FIELD

The present disclosure relates to a display device.

### BACKGROUND ART

As information society develops, the demand for display devices is also increasing in various forms. In response to this, various display devices such as Liquid Crystal Display Device (LCD), Organic Light Emitting Diode (OLED), and Micro LED have been researched and used in recent years.

Among these, a liquid crystal panel includes a TFT substrate and a color filter substrate that face each other with a liquid crystal layer interposed therebetween, and may display an image by using light provided from a backlight unit. In addition, an OLED panel may display an image by depositing an organic material layer capable of self-emitting light on a substrate on which a transparent electrode is formed. In particular, a display device equipped with OLED panel has an advantage of being implemented in an ultra-thin type as it does not require a backlight unit.

A control box may be used to be spaced from the display device, and adjacent to a user. The control box may provide various information to the display device. For example, the control box may be an AV box. The control box may exchange information in a wired/wireless manner with a display head equipped with a display panel that displays images.

Recently, much research has been achieved on the connectivity of such a display device.

### DISCLOSURE OF INVENTION

### Technical Problem

An object of the present disclosure is to solve the above-described problems and other problems.

Another object may be to provide a display device having a wireless communication module.

Another object may be to provide a structure that can effectively dissipate heat from a communication module.

Another object may be to provide a display device that can improve the reception rate of an antenna of communication module.

Another object may be to provide a display device that can secure the rigidity of communication module.

Another object may be to provide a display device that can prevent damage to an input unit provided in a communication module.

### Solution to Problem

According to an aspect of the present disclosure, there is provided a display device including: a display panel; a frame which is located in a rear of the display panel, and to which the display panel is coupled; and a communication module which is adjacent to one side of the frame, is coupled to the frame, and has an antenna unit, wherein the communication module comprises a plate in contact with a rear surface of the antenna unit, wherein a portion of the plate is positioned spaced apart from the antenna unit.

### Advantageous Effects of Invention

The effects of the display device according to the present disclosure will be described as follows.

According to at least one of the embodiments of the present disclosure, there is provided a display device having a wireless communication module may be provided.

According to at least one of the embodiments of the present disclosure, there is provided a structure that can effectively dissipate heat from a communication module.

According to at least one of the embodiments of the present disclosure, there is provided a display device that can improve the reception rate of an antenna of communication module.

According to at least one of the embodiments of the present disclosure, there is provided a display device that can secure the rigidity of communication module.

According to at least one of the embodiments of the present disclosure, there is provided a display device that can prevent damage to an input unit provided in a communication module.

Further scope of applicability of the present disclosure will become apparent from the following detailed description. However, it should be understood that the detailed description and specific embodiments such as preferred embodiments of the present disclosure are given by way of illustration only, since various changes and modifications within the spirit and scope of the present disclosure may be clearly understood by those skilled in the art.

### BRIEF DESCRIPTION OF DRAWINGS

FIGS. 1 to 17 are diagrams illustrating examples of a display device according to embodiments of the present disclosure.

### MODE FOR INVENTION

Description will now be given in detail according to exemplary embodiments disclosed herein, with reference to the accompanying drawings. For the sake of brief description with reference to the drawings, the same or equivalent components may be denoted by the same reference numbers, and description thereof will not be repeated.

In general, suffixes such as “module” and “unit” may be used to refer to elements or components. Use of such suffixes herein is merely intended to facilitate description of the specification, and the suffixes do not have any special meaning or function.

In the present disclosure, that which is well known to one of ordinary skill in the relevant art has generally been omitted for the sake of brevity. The accompanying drawings are used to assist in easy understanding of various technical features and it should be understood that the embodiments presented herein are not limited by the accompanying drawings. As such, the present disclosure should be construed to extend to any alterations, equivalents and substitutes in addition to those which are particularly set out in the accompanying drawings.

It will be understood that although the terms first, second, etc. may be used herein to describe various elements, these elements should not be limited by these terms. These terms are only used to distinguish one element from another.

It will be understood that when an element is referred to as being “connected with” another element, there may be intervening elements present. In contrast, it will be understood that when an element is referred to as being “directly connected with” another element, there are no intervening elements present.

A singular representation may include a plural representation unless context clearly indicates otherwise.

In the present application, it should be understood that the terms “comprises, includes,” “has,” etc. specify the presence of features, numbers, steps, operations, elements, components, or combinations thereof described in the specification, but do not preclude the presence or addition of one or more other features, numbers, steps, operations, elements, components, or combinations thereof.

Direction indications of up (U), down (D), left (Le), right (Ri), front (F), and rear (R) shown in the drawings are only for convenience of explanation, and the technical concept disclosed in this specification is not limited thereto.

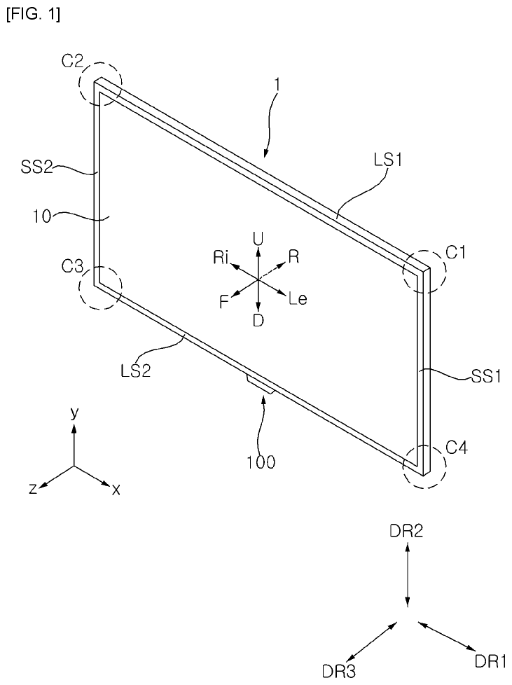

Referring to FIG. 1, a display device 1 may include a display panel 10. The display panel 10 may display a screen.

The display device 1 may include a first long side LS1, a second long side LS2 opposite to the first long side LS1, a first short side SS1 adjacent to the first and second long sides LS1 and LS2, and a second short side SS2 opposite to the first short side SS1. Meanwhile, for convenience of description, it is illustrated that the lengths of the first and second long sides LS1 and LS2 are longer than the lengths of the first and second short sides SS1 and SS2, but it may also be possible that the lengths of the first and second long sides LS1 and LS2 are substantially equal to the lengths of the first and second short sides SS1 and SS2.

The direction parallel to the long sides LS1 and LS2 of the display device 1 may be referred to as a left-right direction or a first direction DR1. The direction parallel to the short sides SS1 and SS2 of the display device 1 may be referred to as an up-down direction or a second direction DR2. The direction perpendicular to the long sides LS1 and LS2 and the short sides SS1 and SS2 of the display device 1 may be referred to as a front-rear direction or a third direction DR3.

The direction in which the display panel 10 displays images may be referred to as a forward direction (F, z), and the opposite direction may be referred to as a rearward direction R. A side of the first long side LS1 may be referred to as an upper side (U, y). A side of the second long side LS2 may be referred to as a lower side D. A side of the first short side SS1 may be referred to as a left side (Le, x). A side of the second short side SS2 may be referred to as a right side Ri.

The first long side LS1, the second long side LS2, the first short side SS1, and the second short side SS2 may be referred to as an edge of the display device 1. In addition, a point where the first long side LS1, the second long side LS2, the first short side SS1, and the second short side SS2 meet each other may be referred to as a corner.

For example, a point where the first short side SS1 and the first long side LS1 meet may be referred to as a first corner C1. A point where the first long side LS1 and the second short side SS2 meet may be referred to as a second corner C2. A point where the second short side SS2 and the second long side LS2 meet may be referred to as a third corner C3. A point where the second long side LS2 and the first short side SS1 meet may be referred to as a fourth corner C4.

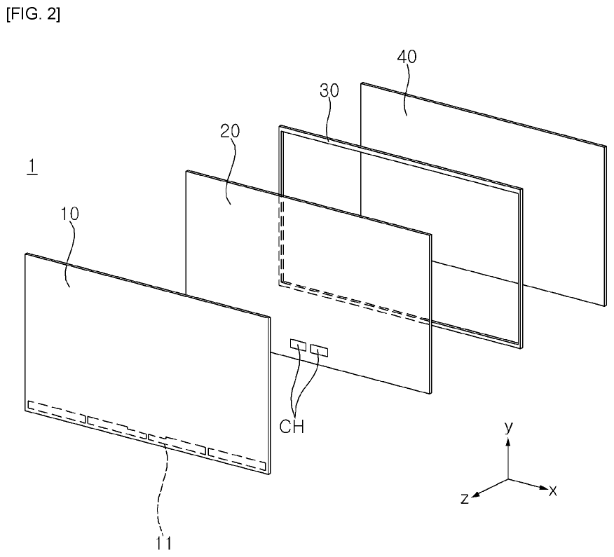

Referring to FIGS. 1 and 2, the display device 1 may include a display panel 10, a frame 20, a side frame 30, and a back cover 40.

The display panel 10 may form the front surface of the display device 1, and display an image in a forward direction. For example, the display panel 10 may be an Organic Light Emitting Diode (OLED) panel. However, the display panel applicable to the present disclosure is not limited to the OLED panel. The display panel 10 may divide an image into a plurality of pixels and output an image with color, brightness, and saturation adjusted for each pixel. The display panel 10 may be divided into an active area where images are displayed and a de-active area where images are not displayed. The display panel 10 may generate light corresponding to the color of red, green, or blue according to a control signal.

The frame 20 may be located in a rear of the display panel 10, and the display panel 10 may be coupled to the frame 20. For example, the frame 20 may include a metal material. Meanwhile, the frame 20 may be referred to as a main frame or module cover.

The side frame 30 may extend along the perimeter of the frame 20. The frame 20 may be coupled to the side frame 30 in front of the side frame 30. The side frame 30 may cover the lateral surfaces of the display panel 10 and the frame 20. Meanwhile, the side frame 30 may be referred to as a guide panel.

The back cover 40 may be located in the rear of the frame 20, and may be coupled to the frame 20. For example, the back cover 40 may be an injection molded product made of resin. For another example, the back cover 40 may include a metal material.

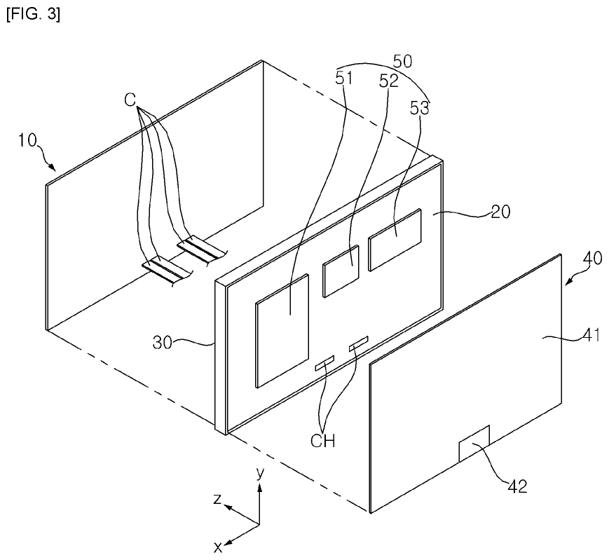

Referring to FIG. 3, boards 50 may be mounted on the frame 20 at the rear of the frame 20. A plurality of electronic devices may be mounted on the boards 50. The board 50 may be a printed circuit board PCB, and may be electrically connected to electronic components of a display device.

For example, the boards 50 may include a power supply board 51 that provides power to each component of the display device, a timing controller board 52 that provides an image signal to the display panel 10, and a main board 53 that controls the display device.

Meanwhile, a Source PCB (S-PCB) 11 (see FIG. 2) may be adjacent to the lower surface of the display panel 10, and may be coupled to the rear surface of the display panel 10. A cable C may pass through a cable hole CH formed in the lower portion of the frame 20, and may be electrically connected to the S-PCB 11 and the timing controller board 52. Accordingly, the cable C may transmit digital video data and timing control signals from the timing controller board 52 to the S-PCB 11. For example, the cable C may be a flexible flat cable FFC.

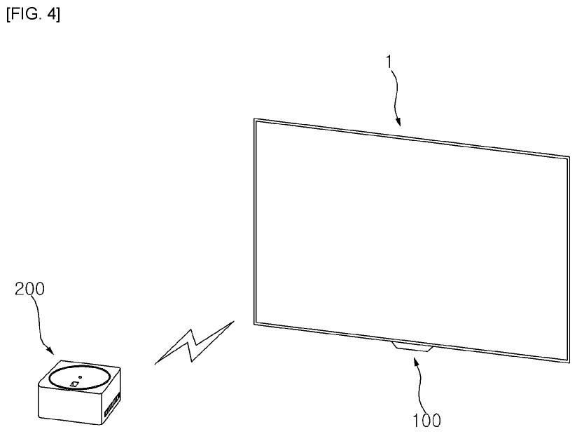

Referring to FIG. 4, the control box 200 may be spaced apart from the display device 1. The control box 200 may be referred to as a set-top box. The control box 200 may wirelessly exchange information with the display device 1. A communication module (not shown) of the control box 200 may communicate wirelessly with the communication module 100 of the display device 1. At least a portion of the communication module 100 may protrude outward from the edge of the display device 1. Accordingly, the communication module 100 may smoothly communicate wirelessly with the communication module of the control box 200.

The stability of wireless communication between the control box 200 and the display device 1 may vary depending on the relative positions of the control box 200 and the display device 1. The display device 1 may be located at a constant location in order to maintain a constant distance from a user. The control box 200 needs to have an enhanced degree of freedom in a place where it is located for user convenience.

Meanwhile, the control box 200 may be a component of the display device 1. In this case, the display device 1 may be referred to as a head 1.

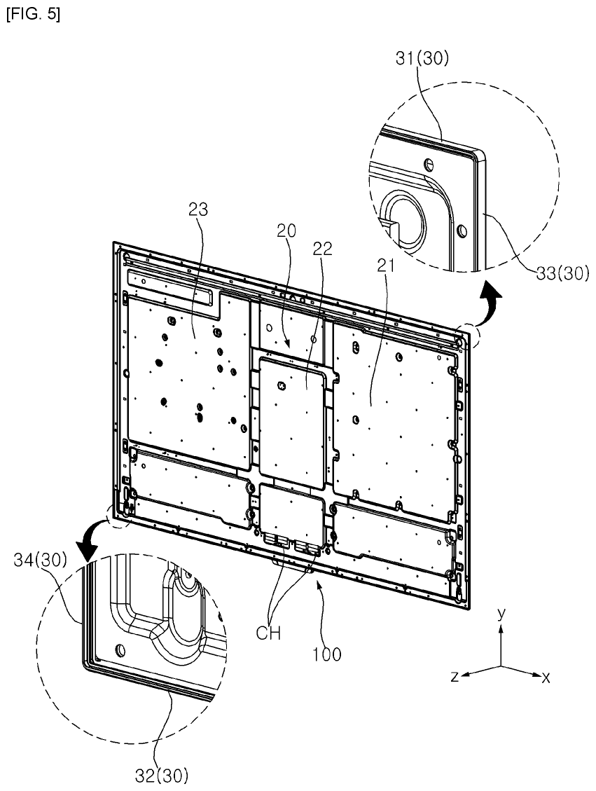

Referring to FIG. 5, the side frame 30 may include a first part 31, a second part 32, a third part 33, and a fourth part 34. The first part 31 may extend along the upper side of the frame 20, and form a first long side LS1 (see FIG. 1). The third part 33 may be bent downward from the left end of the first part 31, may extend along the left side of the frame 20, and may form a first short side SS1 (see FIG. 1). The second part 32 may be bent to the right from the lower distal end of the third part 33, may extend along the lower side of the frame 20, and may form a second long side LS2 (see FIG. 1). The fourth part 34 may be bent upward from the right distal end of the second part 32, may extend along the right side of the frame 20, and may form a second short side SS2 (see FIG. 1).

A first forming part 21, a second forming part 22, and a third forming part 23 may be formed by pressing the frame 20 from the front surface to the rear. The first forming part 21 may be located close to the left side of the frame 20, the third forming part 23 may be located close to the right side of the frame 20, and the second forming part 22 may be located between the first forming part 21 and the third forming part 23. The power supply board 51 (see FIG. 3) may be mounted on the rear surface of the first forming part 21. The timing controller board 52 (see FIG. 3) may be mounted on the rear surface of the second forming part 22. The main board 53 (see FIG. 3) may be mounted on the rear surface of the third forming part 23.

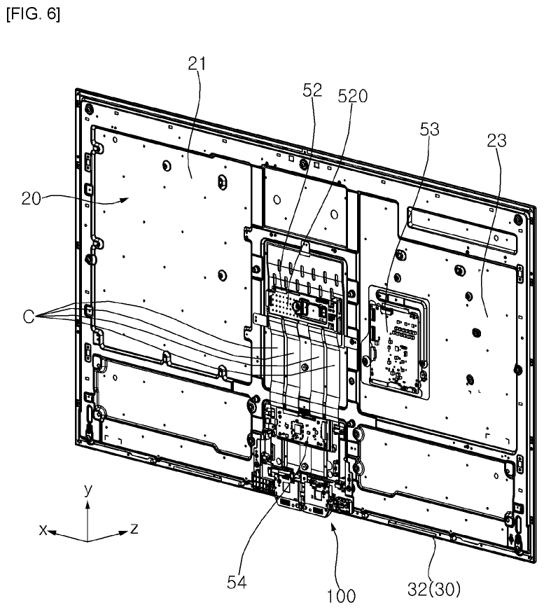

Referring to FIG. 6, a shield plate 520 may be mounted on the rear surface of the timing controller board 52. A first board 54 may be spaced downward from the timing controller board 52, and may be mounted on the rear surface of the frame 20. The second board 53 may be spaced to the right from the timing controller board 52, and may be mounted on the rear surface of the frame 20. A shield plate (not shown) may be mounted on the rear surface of each of the first board 54 and the second board 53. The communication module 100 may receive compressed sound and/or video data from the communication module of the control box 200 (see FIG. 4). The first board 54 may decompress the sound and/or video data received from the communication module 100, convert it, and provide it to the second board 53. The second board 53 may provide data received from the first board 54 to the display panel 10 (see FIG. 3) through the timing controller board 52. In addition, the second board 53 may provide the data received from the first board 54 to a speaker (not shown) that is electrically connected to the second board 53 through a cable or the like and provided in the display device. The first board 54 may be referred to as an RF receiving device, an RF processing device, or a wireless audio video (WAV) board. The second board 53 may be referred to as an amplifier (AMP) board. For example, the second board 53 may be a main board 53.

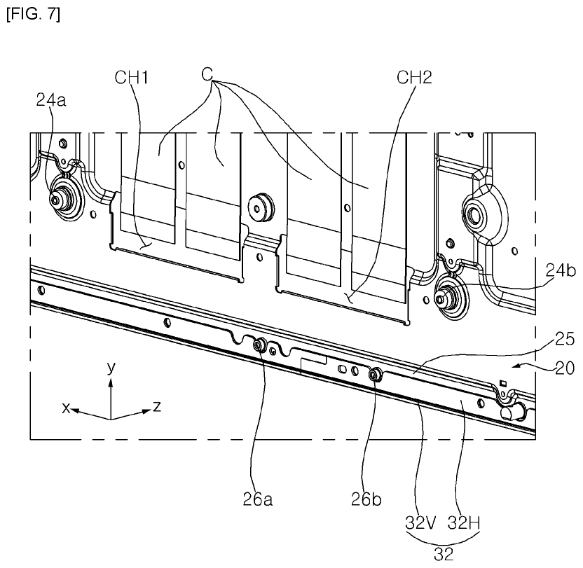

Referring to FIG. 7, a first cable hole CH1 and a second cable hole CH2 may be formed to penetrate the frame 20 in the front-rear direction, and may be adjacent to the second part 32. The first cable hole CH1 may be adjacent to, but may be spaced apart from, the second cable hole CH2. For example, four cables C may form a pair by using every two cables, one pair may pass through the first cable hole CH1, and the other pair may pass through the second cable hole CH2.

The second part 32 may include a vertical portion 32V and a horizontal portion 32H.

The vertical portion 32V may extend along the lower side of the frame 20, and may form the lower side of the second part 32. The vertical portion 32V may have a width in a direction intersecting the frame 20. In other words, the length of the vertical portion 32V may be defined in the left-right direction, the width of the vertical portion 32V may be defined in the front-rear direction, and the thickness of the vertical portion 32V may be defined in the up-down direction.

The horizontal portion 32H may protrude from the upper side of the frame 20 toward the rear of the frame 20. The horizontal portion 32H may be disposed parallel to the frame 20 at the rear of the frame 20. In other words, the length of the horizontal portion 32H may be defined in the left-right direction, the width of the horizontal portion 32H may be defined in the up-down direction, and the thickness of the horizontal portion 32H may be defined in the front-rear direction.

Meanwhile, a pressing portion 25 may be formed by pressing toward from the rear surface of the frame 20, and may form the lower side of the frame 20. The front surface of the pressing portion 25 may contact the rear surface of the horizontal portion 32H. The horizontal portion 32H may be coupled to or fixed to the pressing portion 25.

A lower fixing portion 26a, 26b may protrude from the pressing portion 25 toward the horizontal portion 32H, and may penetrate the horizontal portion 32H. A first lower fixing portion 26a may be spaced to the left from a second lower fixing portion 26b. An upper fixing portion 24a, 24b may protrude rearward from the frame 20. A first upper fixing portion 24a may be adjacent to the first cable hole CH1, and a second upper fixing portion 24b may be adjacent to the second cable hole CH2.

For example, the lower fixing portion 26a, 26b and the upper fixing portion 24a, 24b may be a pemnut.

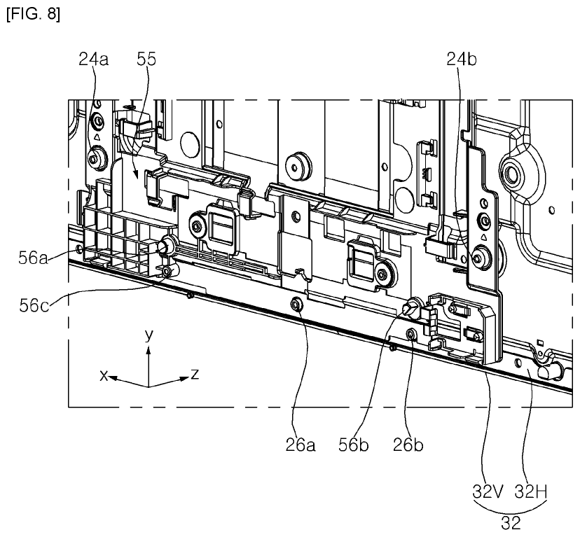

Referring to FIG. 8, a base 55 may be detachably coupled to the frame 20 and the second part 32 at the rear of the frame 20. The base 55 may be located above the vertical portion 32V. A portion of the base 55 may cover at least a portion of the rear of the cable hole CH1, CH2 (see FIG. 7). A portion of the base 55 may cover a portion of the rear surface of the horizontal portion 32H. The lower fixing portion 26a, 26b and the upper fixing portion 24a, 24b may penetrate the base 55.

A boss 56a, 56b, and the third lower fixing portion 56c may protrude rearward from the base 55. The third lower fixing portion 56c may be adjacent to the vertical portion 32V, and may be opposite to the horizontal portion 32H with respect to the base 55. The third lower fixing portion 56c may be opposite to the second lower fixing portion 26b with respect to the first lower fixing portion 26a. The first boss 56a may be adjacent to the third lower fixing portion 56c, but may be spaced upward from it. The second boss 56b may be adjacent to the second lower fixing portion 26b, but may be spaced upward from it. For example, the third lower fixing portion 56c may be a pemnut. Meanwhile, the boss 56a, 56b may be referred to as a fixing pin.

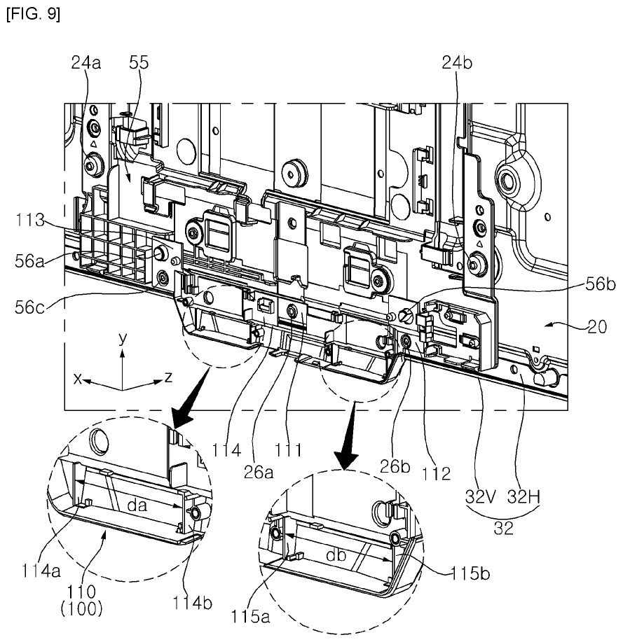

Referring to FIG. 9, a front housing 110 may be detachably coupled to the base 55 at the rear of the base 55. A first portion, which is a portion of the front housing 110, may be located above the vertical portion 32V, and a second portion, which is the remaining portion of the front housing 110, may be located below the vertical portion 32V. The first portion may form the front surface of the communication module 100. The first portion and the second portion may be formed as one body.

The first portion may include a first coupling portion 111, a second coupling portion 112, and a third coupling portion 113. The first coupling portion 111 may be located approximately in the center of the first portion, and the third coupling portion 113 may be opposite to the second coupling portion 112 with respect to the first coupling portion 111. The first lower fixing portion 26a may penetrate the first coupling portion 111. The second lower fixing portion 26b may penetrate the second coupling portion 112. The third lower fixing portion 56c may penetrate the third coupling portion 113.

The second portion may include a pair of left ribs 114a and 114b and a pair of right ribs 115a and 115b provided inside the second portion. The pair of left ribs 114a and 114b and the pair of right ribs 115a and 115b may be spaced apart from each other in the left-right direction, and may be disposed vertically inside the second portion. A partition wall 114 may be located at the boundary between the first portion and the second portion, and may extend in the left-right direction to contact or be adjacent to the inside of the front housing 110. In this case, the pair of left ribs 114a and 114b and the pair of right ribs 115a and 115b may be coupled to the lower side of the partition wall 114. A first left rib 114a may be adjacent to the left side of the second portion, and a second left rib 114b may be spaced to the right by a first distance da from the first left rib 114a. The first right rib 115a may be opposite to the first left rib 114a with respect to the second left rib 114b. The second right rib 115b may be spaced to the right by a second distance db from the first right rib 115a, and may be adjacent to the right side of the second portion.

For example, the first distance da may be substantially equal to the second distance db. For another example, the first distance da may be smaller or larger than the second distance db.

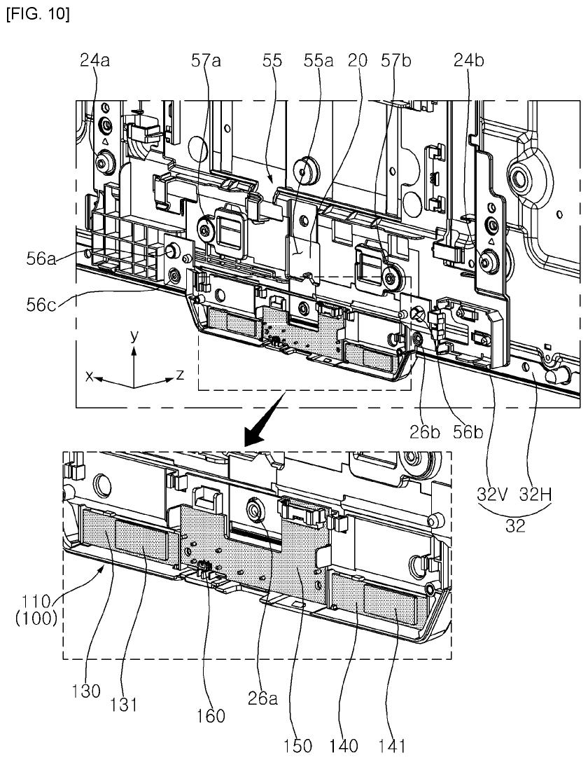

Referring to FIGS. 9 and 10, the communication module 100 may include an antenna unit 130, 140. The number of antenna unit 130, 140 may be one or two or more. A first antenna unit 130 may be disposed between a pair of left ribs 114a and 114b. A first pad 131 may be coupled or attached to the rear surface of the first antenna unit 130. The first pad 131 may include a material having an excellent thermal conductivity, and may be referred to as a thermal pad. A second antenna unit 140 may be disposed between a pair of right ribs 115a and 115b. A second pad 141 may be coupled or attached to the rear surface of the second antenna unit 140. The second pad 141 may include a material having an excellent thermal conductivity, and may be referred to as a thermal pad. Meanwhile, the first antenna unit 130 may be referred to as a left antenna unit, and the second antenna unit 140 may be referred to as a right antenna unit.

For example, a patch antenna may be provided on the front surface of each of the first antenna unit 130 and the second antenna unit 140. For example, an array antenna using a dipole antenna or a monopole antenna may be provided on the left and lower side surfaces of the first antenna unit 130. For example, an array antenna using a dipole antenna or a monopole antenna may be provided on the right and lower side surfaces of the second antenna unit 140. The array antenna may have an end-fire shape.

For example, the first antenna unit 130 and the second antenna unit 140 may have a different polarization characteristic. For example, the first antenna unit 130 may have a vertical polarization characteristic. For example, the second antenna unit 140 may have a horizontal polarization characteristic. Here, polarization refers to a polarity direction of an electric field with respect to the direction of electromagnetic wave from the antenna.

An Infrared (IR) module 150 may be disposed between the second left rib 114b and the first right rib 115a. The IR module 150 may include a controller. An input unit 160 may be adjacent to the lower side of the IR module 150. The input unit 160 may be exposed to the lower side of the front housing 110. Meanwhile, the input unit 160 may be referred to as a power unit or button.

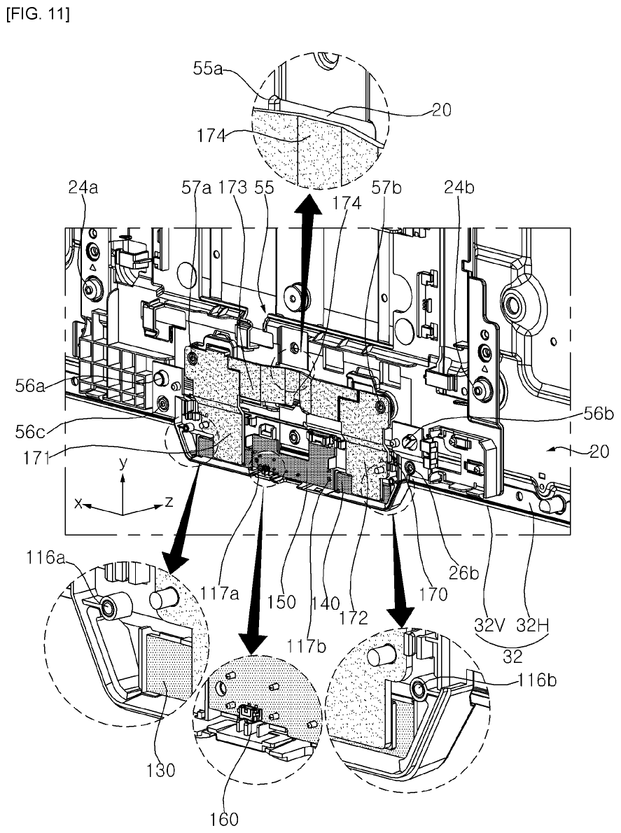

Referring to FIGS. 10 and 11, a plate fixing portion 57a, 57b may protrude rearward from the base 55, and may be located above the front housing 110. A first plate fixing portion 57a and a second plate fixing portion 57b may be spaced apart from each other in the left-right direction. For example, the plate fixing portion 57a, 57b may be a pemnut.

The plate 170 may be detachably coupled to the base 55 and the front housing 110 at the rear of the base 55 and the front housing 110. The plate 170 may cover a portion of the rear of the base 55 and a portion of the rear of the front housing 110. The plate fixing portion 57a, 57b may penetrate the plate 170. The plate 170 may include a material having an excellent thermal conductivity, and may be referred to as a heat sink. The plate 170 may have an overall square bracket shape, and may include a first plate 171, a second plate 172, and a third plate 173.

The first plate 171 may be located at a rear of the first antenna unit 130, and may extend long in the up-down direction. For example, the first plate 171 may be bent at least once, and an imaginary horizontal plane (i.e., an XY plane) on which an upper portion of the first plate 171 is located may be located at a rear of an imaginary horizontal plane (i.e., an XY plane) on which a lower portion of the first plate 171 is located. The rear surface of the first pad 131 may contact the lower portion of the first plate 171. That is, heat generated by the first antenna unit 130 may be transmitted to the lower portion of the first plate 171 through the first pad 131, and the heat may be transmitted from the lower portion of the first plate 171 to the upper portion of the first plate 171. Accordingly, heat of the first antenna unit 130 may be effectively removed.

The second plate 172 may be located at a rear of the second antenna unit 140, and may extend long in the up-down direction. For example, the second plate 172 may be bent at least once, the upper portion of the second plate 172 may be located on the horizontal plane where the upper portion of the first plate 171 is located, and the lower portion of the second plate 172 may be located on the horizontal plane where the lower portion of the first plate 171 is located. The rear surface of the second pad 141 may contact the lower portion of the second plate 172. That is, the heat generated by the second antenna unit 140 may be transmitted to the lower portion of the second plate 172 through the second pad 141, and may be transmitted from the lower portion of the second plate 172 to the lower portion. Accordingly, heat of the second antenna unit 140 may be effectively removed.

The third plate 173 may extend long between the upper portion of the first plate 171 and the upper portion of the second plate 172, and may be connected to the upper portion of the first plate 171 and the upper portion of the second plate 172. The third plate 173 may be located above the IR module 150. For example, the first plate 171, the second plate 172, and the third plate 173 may be formed separately, or may be coupled to each other. For another example, the first plate 171, the second plate 172, and the third plate 173 may be formed as one body.

For example, a press portion 174 may be formed by pressing the third plate 173 toward the frame 20, and may be located approximately in the center of the plate 170. A base hole 55a may be formed to penetrate the base 55 in the front-rear direction, and the press portion 174 may contact the rear surface of the frame 20 through the base hole 55a. That is, the heat of the third plate 173 may be easily transmitted to the frame 20. Accordingly, heat dissipation of the first antenna unit 130 and the second antenna unit 140 may be achieved more effectively.

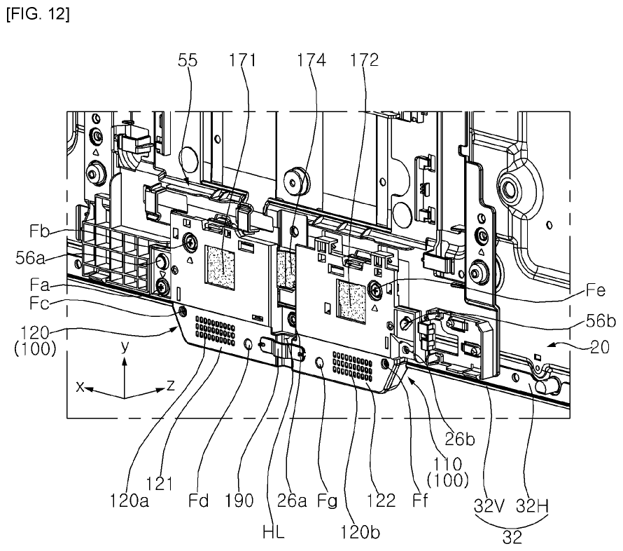

Referring to FIGS. 11 and 12, a housing fixing portion 116a, 116b may protrude rearward from the inside of the front housing 110, and may be located on the partition wall 114. A first housing fixing portion 116a may be adjacent to the left side of the front housing 110, and a second housing fixing portion 116b may be adjacent to the right side of the front housing 110. For example, the housing fixing portion 116a, 116b may be a pemnut. A board pin 117a, 117b may protrude rearward from the IR module 150. A first board pin 117a may be adjacent to the left side of the IR module 150, and a second board pin 117b may be adjacent to the right side of the IR module 150.

A rear housing 120 may be detachably coupled to the base 55 and the front housing 110 at the rear of the plate 170. The rear housing 120 may form the rear surface of the communication module 100. The rear housing 120 may include a first housing 121 and a second housing 122.

The first housing 121 may be located at a rear of the first plate 171. A first opening (not denoted) may be formed to penetrate the first housing 121 in the front-rear direction, and may be located at the rear of the upper portion of the first plate 171. A first hole 120a may be formed to penetrate the first housing 121 in the front-rear direction, and may be located at the rear of the first antenna unit 130. Accordingly, the first antenna unit 130 may be cooled by air passing through the first hole 120a.

The second housing 122 may be located at a rear of the second plate 172. A second opening (not denoted) may be formed to penetrate the second housing 122 in the front-rear direction, and may be located at the rear of the upper portion of the second plate 172. A second hole 120b may be formed to penetrate the second housing 122 in the front-rear direction, and may be located at the rear of the second antenna unit 140. Accordingly, the second antenna unit 140 may be cooled by air passing through the second hole 120b.

A middle portion (no reference numeral) of the rear housing 120 may connect the first housing 121 and the second housing 122 at between the first housing 121 and the second housing 122. For example, the first housing 121, the second housing 122, and the middle portion may be formed as one body.

In addition, the first boss 56a may penetrate the first housing 121, and the second boss 56b may penetrate the second housing 122. Accordingly, the first boss 56a and the second boss 56b may guide the coupling of the rear housing 120 with respect to the base 55 and the front housing 110.

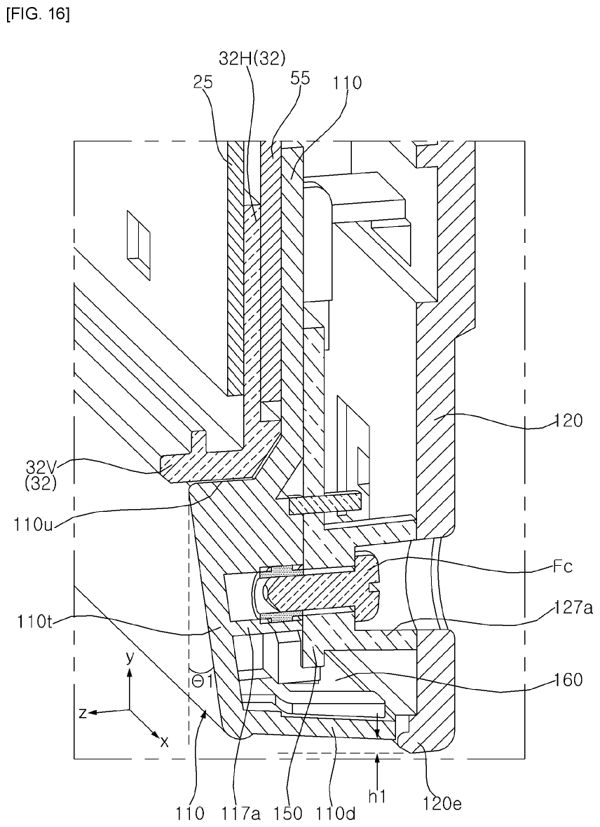

In addition, a fastening member (not shown) may penetrate the middle portion, and may be fastened to the first lower fixing portion 26a. A first fastening member Fa may penetrate the first housing 121, and may be fastened to the third lower fixing portion 56c. A second fastening member Fb may penetrate the first housing 121, and may be fastened to the first plate fixing portion 57a. A third fastening member Fc may penetrate the first housing 121, and may be fastened to the first housing fixing portion 116a. A fourth fastening member Fd may penetrate the first housing 121 and the first board pin 117a, and may be fastened to the inside of the front housing 110 (see FIG. 16). A fifth fastening member (not shown) may penetrate the second housing 122, and may be fastened to the second lower fixing portion 26b. A sixth fastening member (Fe) may penetrate the second housing 122, and may be fastened to the second plate fixing portion 57b. A seventh fastening member Ff may penetrate the second housing 122, and may be fastened to the second housing fixing portion 116b. An eighth fastening member Fg may penetrate the second housing 122 and the second board pin 117b, and may be fastened to the inside of the front housing 110.

Accordingly, the communication module 100 may be coupled to the frame 20, the pressing portion 25 (see FIG. 7), the second part 32, and the base 55, and the rigidity of the communication module 100 may be enhanced.

Meanwhile, the fastening members may be a screw. In addition, the fastening members may be spaced apart from the antenna unit 130, 140 by a certain distance or more. The fastening members may not overlap the antenna unit 130, 140 in the front-rear direction. Accordingly, beam distortion and performance degradation of the antenna unit 130, 140 caused by the fastening members may be minimized.

Meanwhile, the press portion 174 may be located between the first housing 121 and the second housing 122. The holder 190 may be fixed to the first housing 121 and the second housing 122. A cable passage HL may be formed between the holder 190 and the middle portion.

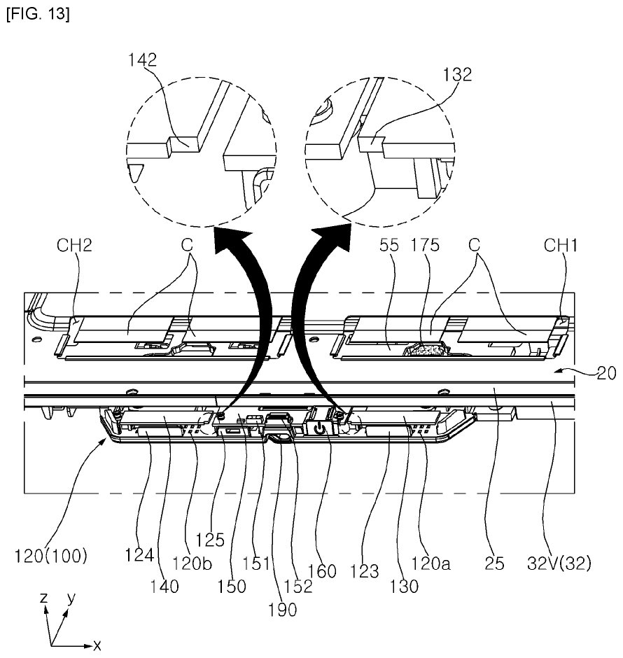

Referring to FIGS. 11 and 13, an insertion portion 175 may protrude from the upper end of the first plate 171 toward the frame 20, and may be inserted into the frame 20. Accordingly, the insertion portion 175 may guide the coupling of the plate 170 with respect to the frame 20. In addition, a user may easily determine a correct position of the first plate 171 and the second plate 172 with respect to the frame 20 through the insertion portion 175.

A first cut-out 132 may be formed at a corner where the lower side and the right side of the first antenna unit 130 meet. A second cut-out 142 may be formed at a corner where the lower side and the left side of the second antenna unit 140 meet. Accordingly, a user may easily determine the installation locations of the first antenna unit 130 and the second antenna unit 140 with respect to the interior of the communication module 100 through the locations of the first cut-out 132 and the second cut-out 142.

A first seating portion 123 may be provided inside the rear housing 120, and the first pad 131 (see FIG. 10) or the first plate 171 (see FIG. 11) may be seated on the first seating portion 123. A second seating portion 124 may be provided inside the rear housing 120, and the second pad 141 (see FIG. 10) or the second plate 172 (see FIG. 11) may be seated on the second seating portion 124. Accordingly, the first antenna unit 130 and the second antenna unit 140 may be spaced upward from the lower end of the rear housing 120.

A third seating portion 125 may be provided inside the rear housing 120, and the IR module 150 may be seated on the third seating portion 125. An IR unit 151 may be provided on the front surface of the IR module 150. An indicator 152 may be provided on the front surface of the IR module 150, and may be adjacent to the IR unit 151. The front housing 110 may include a translucent material.

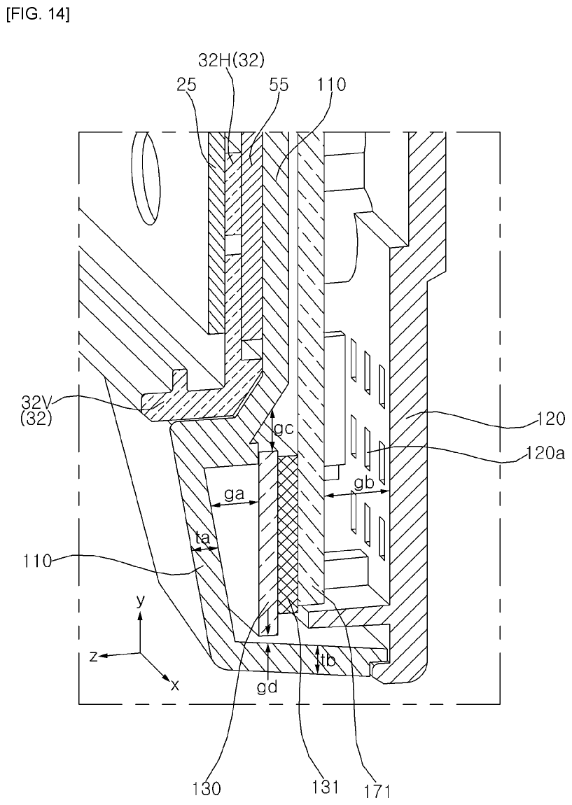

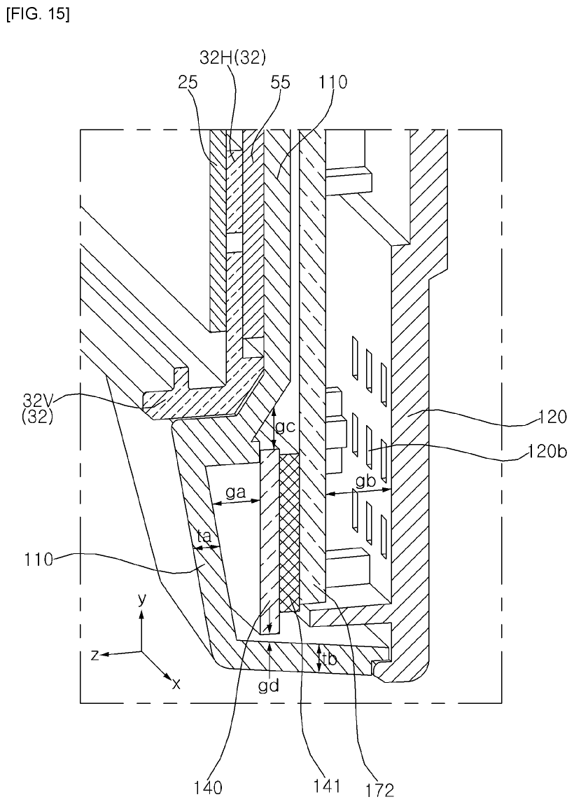

Referring to FIGS. 14 and 15, the first antenna unit 130 and the second antenna unit 140 may be spaced apart from the inside of the front housing 110 and the inside of the rear housing 120.

In the front-rear direction, the front surface of the first antenna unit 130 and the front surface of the second antenna unit 140 may be spaced apart from the front housing 110 by a first gap ga. In the front-rear direction, the rear surface of the first plate 171 and the rear surface of the second plate 172 may be spaced apart from the inside of the rear housing 120 by a second gap gb. In the up-down direction, the upper end of the first antenna unit 130 and the upper end of the second antenna unit 140 may be spaced apart from the front housing 110 by a third gap gc. In the up-down direction, the lower end of the first antenna unit 130 and the lower end of the second antenna unit 140 may be spaced apart from the front housing 110 by a fourth gap gd.

For example, the first gap ga may be 1 to 4.5 mm, and the fourth gap gd may be 1 mm or less. For example, the second gap gb may be larger than the first gap ga, and the third gap gc may be larger than the fourth gap gd. For example, the left side of the first antenna unit 130 may be spaced apart from the left side of the front housing 110 by a gap of 0.5 mm or less. For example, the right side of the second antenna unit 130 may be spaced apart from the right side of the front housing 110 by a gap of 0.5 mm or less.

For example, the thickness ta of the front end of the front housing 110, the thickness tb of the lower end, the thickness of the left end, and the thickness of the right end may be 1 to 1.5 mm. For example, the front housing 110 may include resin. For example, the front housing 110 may include polycarbonate (PC).

Accordingly, beam distortion and performance degradation of the first antenna unit 130 and the second antenna unit 140 caused by the front housing 110 may be minimized.

The thickness of the rear housing 120 may be 1 to 1.5 mm. For example, the rear housing 120 may include resin. For example, rear housing 120 may include PC ABS.

Accordingly, beam distortion and performance degradation of the first antenna unit 130 and the second antenna unit 140 caused by the rear housing 120 may be minimized. In addition, the heat from the first antenna unit 130 and the second antenna unit 140 can be easily radiated to the outside through the rear housing 120.

Referring to FIG. 16, a contact portion 110u of the front housing 110 may contact the lower side of the vertical portion 32V, and may be spaced rearward from the front end of the vertical portion 32V. The front surface 110t of the front housing 110 may be inclined in a rearward direction with respect to the contact portion 110u (see theta 1). The lower surface 110d of the front housing 110 may be spaced upward by a certain distance h1 from the lower end 120e of the rear housing 120.

In this case, the input unit 160 provided on the lower surface 110d may be spaced upward from the lower end 120e. Accordingly, when the lower end of the display device is placed on an object during the manufacturing process, transportation work, or installation work of the display device, the lower end 120e of the rear housing 120 may contact the object, and the input unit 160 may be spaced apart from the object. In other words, damage to the input unit 160 caused by the object can be prevented.

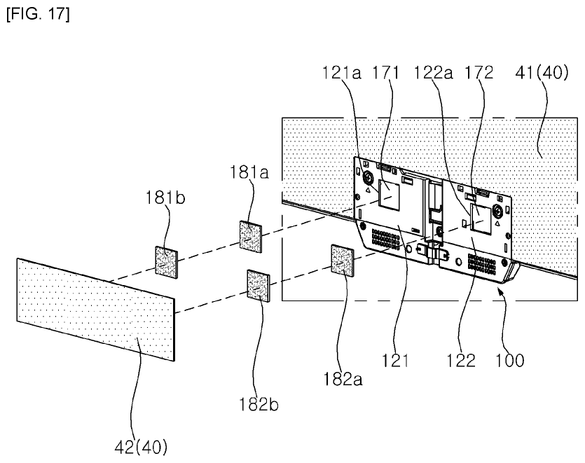

Referring to FIG. 17, the back cover 40 may include a first cover 41 and a second cover 42. The first cover 41 may cover the rear of the frame 20 (see FIG. 3), and the second cover 42 may cover the rear of a portion overlapping with the frame 20 of the communication module 100 in the front-rear direction. The second cover 42 may be detachably coupled to the communication module 100. Accordingly, a user may separate the second cover 42 from the communication module 100, and easily access the rear surface of the communication module 100.

The upper portion of the first plate 171 may face the second cover 42 through a first opening 121a formed in the first housing 121. A first gap pad 181a, 181b may be disposed between the upper portion of the first plate 171 and the second cover 42, and may be in contact with the upper portion of the first plate 171 and the second cover 42. The first gap pad 181a, 181b may include a material having an excellent thermal conductivity. For example, the first gap pad 181a, 181b may include graphite. For example, the first gap pad 181a, 181b may include at least one layer containing graphite.

The upper portion of the second plate 172 may face the second cover 42 through a second opening 122a formed in the second housing 122. A second gap pad 182a, 182b may be disposed between the upper portion of the second plate 172 and the second cover 42, and may be in contact with the upper portion of the second plate 172 and the second cover 42. The second gap pad 182a, 182b may include a material having an excellent thermal conductivity. For example, the second gap pad 182a, 182b may include graphite. For example, the second gap pad 182a, 182b may include at least one layer containing graphite.

Accordingly, the heat of the upper portion of the first plate 171 and the heat of the upper portion of the second plate 172 may be easily transmitted to the second cover 42 through the gap pad 181a, 181b, 182a, and 182b. As a result, the heat dissipation performance of the first antenna unit 130 and the second antenna unit 140 of the communication module 100 can be improved (see FIG. 11).

According to an aspect of the present disclosure, a display device includes: a display panel; a frame which is located in a rear of the display panel, and to which the display panel is coupled; and a communication module which is adjacent to one side of the frame, is coupled to the frame, and has an antenna unit, wherein the communication module comprises a plate in contact with a rear surface of the antenna unit, wherein a portion of the plate is positioned spaced apart from the antenna unit.

In addition, according to another aspect of the present disclosure, the antenna unit may be located below a lower side of the frame, and the plate may extend upward from the antenna unit.

In addition, according to another aspect of the present disclosure, the antenna unit may include: a first antenna unit; and a second antenna unit spaced apart from the first antenna unit in a longitudinal direction of one side of the frame, wherein the plate may include: a first plate in contact with a rear surface of the first antenna unit; a second plate in contact with a rear surface of the second antenna unit; and a third plate positioned between the first plate and the second plate, and connected to the first plate and the second plate.

In addition, according to another aspect of the present disclosure, the plate may further include a press portion which is formed by pressing from the third plate toward the frame, and which may be in contact with the frame.

In addition, according to another aspect of the present disclosure, the communication module may further include a back cover covering a rear of the frame, wherein a lower portion of the plate may be in contact with a rear surface of the antenna unit, wherein an upper portion of the plate may be located between the frame and the back cover, wherein the communication module may further include a gap pad which is located between the upper portion of the plate and the back cover, and which is in contact with the upper portion of the plate and the back cover.

In addition, according to another aspect of the present disclosure, the gap pad may include at least one layer including graphite.

In addition, according to another aspect of the present disclosure, a portion of the back cover may be detachably coupled to the communication module at a rear of the communication module.

In addition, according to another aspect of the present disclosure, the communication module may include a housing which provides an internal space where the antenna unit and the plate are located, wherein the housing may include a hole which is formed to penetrate the housing, and which faces a rear surface of the antenna unit.

In addition, according to another aspect of the present disclosure, the antenna unit may be adjacent to one side of the frame at the outside of the frame, wherein a portion of the communication module may surround the antenna unit, may be spaced apart from the antenna unit, and may have a thickness of 1 to 1.5 mm.

In addition, according to another aspect of the present disclosure, a portion of the communication module may be located in front of the antenna unit, and may include a polycarbonate (PC) material.

In addition, according to another aspect of the present disclosure, the frame may further include a lower fixing portion protruding in a rearward direction from the frame, wherein the communication module may include: a front housing coupled to the lower fixing portion at a rear of the frame; and a rear housing coupled to the lower fixing portion at a rear of the front housing.

In addition, according to another aspect of the present disclosure, the frame may further include a pressing portion which is formed by pressing one side of the frame to the other side, and at which the lower fixing portion is located.

In addition, according to another aspect of the present disclosure, the display device may further include a side frame which extends along the one side of the frame, which is fixed to the pressing portion, and through which the lower fixing portion passes.

In addition, according to another aspect of the present disclosure, the display device may further include a base which is located between the frame and the front housing, and through which the lower fixing portion passes, wherein the base may include a boss protruding from the base toward the front housing and inserted into the front housing.

In addition, according to another aspect of the present disclosure, the communication module may further include: a housing which provides an internal space where the antenna unit is located; an IR module which is located in the internal space of the housing, and which is adjacent to the antenna unit; and an input unit adjacent to the IR module, wherein the antenna unit may include: a first antenna unit; and a second antenna unit opposite to the first antenna unit with respect to the IR module, wherein the input unit may be located above a lower end of the housing.

Certain embodiments or other embodiments of the disclosure described above are not mutually exclusive or distinct from each other. Any or all elements of the embodiments of the disclosure described above may be combined or combined with each other in configuration or function.

For example, a configuration “A” described in one embodiment of the disclosure and the drawings and a configuration “B” described in another embodiment of the disclosure and the drawings may be combined with each other. Namely, although the combination between the configurations is not directly described, the combination is possible except in the case where it is described that the combination is impossible.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A display device comprising:
a display panel;
a frame which is located in a rear of the display panel, and to which the display panel is coupled; and
a communication module which is adjacent to one side of the frame, is coupled to the frame, and has an antenna unit,
wherein the communication module comprises a plate in contact with a rear surface of the antenna unit,
wherein a portion of the plate is positioned spaced apart from the antenna unit.

2. The display device of claim 1, wherein the antenna unit is located below a lower side of the frame,
wherein the plate extends upward from the antenna unit.

3. The display device of claim 2, wherein the antenna unit comprises:
a first antenna unit; and
a second antenna unit spaced apart from the first antenna unit in a longitudinal direction of one side of the frame,
wherein the plate comprises:
a first plate in contact with a rear surface of the first antenna unit;
a second plate in contact with a rear surface of the second antenna unit; and
a third plate positioned between the first plate and the second plate and connected to the first plate and the second plate.

4. The display device of claim 3, wherein the plate further comprises a press portion which is formed by pressing from the third plate toward the frame, and which is in contact with the frame.

5. The display device of claim 1, wherein the communication module further comprises a back cover covering a rear of the frame,
wherein a lower portion of the plate is in contact with a rear surface of the antenna unit,
wherein an upper portion of the plate is located between the frame and the back cover,
wherein the communication module further comprises a gap pad which is located between the upper portion of the plate and the back cover, and which is in contact with the upper portion of the plate and the back cover.

6. The display device of claim 5, wherein the gap pad comprises at least one layer including graphite.

7. The display device of claim 5, wherein a portion of the back cover is detachably coupled to the communication module at a rear of the communication module.

8. The display device of claim 1, wherein the communication module comprises a housing which provides an internal space where the antenna unit and the plate are located,
wherein the housing comprises a hole which is formed to penetrate the housing, and which faces a rear surface of the antenna unit.

9. The display device of claim 1, wherein the antenna unit is adjacent to one side of the frame at the outside of the frame,
wherein a portion of the communication module surrounds the antenna unit, is spaced apart from the antenna unit, and has a thickness of 1 to 1.5 mm.

10. The display device of claim 9, wherein a portion of the communication module is located in front of the antenna unit, and comprises a polycarbonate (PC) material.

11. The display device of claim 1, wherein the frame further comprises a lower fixing portion protruding in a rearward direction from the frame,
wherein the communication module comprises:
a front housing coupled to the lower fixing portion at a rear of the frame; and
a rear housing coupled to the lower fixing portion at a rear of the front housing.

12. The display device of claim 11, wherein the frame further comprises a pressing portion which is formed by pressing one side of the frame to the other side, and at which the lower fixing portion is located.

13. The display device of claim 12, further comprising a side frame which extends along the one side of the frame, which is fixed to the pressing portion, and through which the lower fixing portion passes.

14. The display device of claim 11, further comprising a base which is located between the frame and the front housing, and through which the lower fixing portion passes,
wherein the base comprises a boss protruding from the base toward the front housing and inserted into the front housing.

15. The display device of claim 1, wherein the communication module further comprises:
a housing which provides an internal space where the antenna unit is located;
an IR module which is located in the internal space of the housing, and which is adjacent to the antenna unit; and
an input unit adjacent to the IR module,
wherein the antenna unit comprises:
a first antenna unit; and
a second antenna unit opposite to the first antenna unit with respect to the IR module,
wherein the input unit is located above a lower end of the housing.
